(19) United States
(12) Patent Application Publication
(10) Pub. No.: US 2022/0164062 A1
(43) Pub. Date: May 26, 2022

(54) TOUCHSCREEN DEVICE

(71) Applicants: Innostar Service Inc., Taichung (TW); Naviance Semiconductor Limited, Hsinchu County (TW)

(72) Inventors: MENG-CHIH WU, Taichung (TW); CHIEN-KUO TIEN, Hsinchu County (TW); CHUN-CHUNG LIN, Hsinchu County (TW)

(21) Appl. No.: 16/953,354

(22) Filed: Nov. 20, 2020

(51) Int. Cl. G06F 3/042; H01L 25/16; G06F 3/041

(52) U.S. Cl. CPC G06F 3/0421; G06F 3/0412; H01L 25/167

(57) ABSTRACT

A touch panel includes a display substrate, pixel units supported on the display substrate, an electronic circuit for electrically connecting the pixel units to one another, and a molded resin portion for enclosing the pixel units. Each of the pixel units includes three miniature light-emitting diodes for emitting red light, green light and blue light respectively, a sensor, and a driver integrated circuit electrically connected to the miniature light-emitting diodes and the sensor.

### BACKGROUND OF INVENTION

### 1. Field of Invention

The present invention relates to a light-emitting diode (“LED”) display device and, more particularly, to an LED-based touchscreen device.

### 2. Related Prior Art

Typically a touchscreen is used on a sensitive display, an LED panel, a flat panel display or an electronic-ink device to receive signals from a tip of a finger or a tip of a pen. For using a user-friendly human-machine interface, touchscreens are widely used on automatic teller machines, bond pads, industrial computers and smart phones.

A typical touchscreen device includes a touch panel and a display panel. The touch panel is located on the display panel according to on-cell techniques often used for a thin-film transistor (“TFT”) and an organic light-emitting diode (“OLED”). However, the touchscreen device fails to include a completely dark screen.

In-cell techniques have been devised to merge a touch panel with a display panel to make a resultant touchscreen device lighter, thinner and smaller than before. In detail, a touch-panel IC is merged with a display IC into a control IC to reduce the thickness of the touchscreen device, interferences with circuits and complexity in stacking and achieve high integration. However, all these together become a grave entry barrier for the industry of touchscreen devices.

Based on principles of sensing, the touch panels can be classified into a capacitor type, a resistor type and a fluctuating type. A resistor-type touch panel includes non-conductive spheres to separate two glass panels. A conductive layer is attached to a face of each of the glass panels and a scratch-proof panel is attached to another face of each of the glass panels. The conductive layer includes an indium tin oxide (“ITO”) and is used as an electrode. A short circuit is produced to change the resistance when the electrodes attached to the glass panels are in contact with each other when the glass panels are pushed toward each other. A change in the voltage is detected and calculated to determine the location of the point of contact.

A capacitor-type touch panel is a laminate of multiple layers of transparent materials. An external layer is the hardest layer. An internal layer is doped with ITO and used as a shield. An intermediate layer includes ITO and is used as an working layer to lead four electrodes to corners or edges. A very small current is driven from each of the electrodes when a tip of a finger skids over the capacitor-type touch panel. A ratio of the currents is calculated to determine the distances of the point of contact from the corners or edges. Thus, the location of the point of contact is determined.

A fluctuating-type touch panel includes ultrasonic transmitters and receivers attached to corners of a glass substrate and reflective strips attached to edges of the glass substrate. When a tip of a finger or another object touches the glass substrate, the finger or other object stops the advancing of ultrasonic signals. Attenuation occurs when each of the receivers fails to receive an ultrasonic signal. The signal strength after the attenuation is compared with the signal strength before the attenuation to determine the location of the point of contact. In addition, infrared transmitters and receivers can be arranged by the glass substrate. Thus, an infrared grid is produced by the infrared transmitters and receivers when they are turned on. The tip of a finger or another object can interfere with the infrared grid, i.e., one of the infrared receivers fails to receive an infrared signal from a corresponding one of the infrared transmitters. Thus, the location of the point of contact can be determined.

The present invention is therefore intended to obviate or at least alleviate the problems encountered in the prior art.

### SUMMARY OF INVENTION

It is the primary objective of the present invention to provide a touch panel which also works as a display panel.

To achieve the foregoing objective, the touch panel includes a display substrate, pixel units supported on the display substrate, an electronic circuit for electrically connecting the pixel units to one another, and a molded resin portion for enclosing the pixel units. Each of the pixel units includes three miniature light-emitting diodes for emitting red light, green light and blue light respectively, a sensor, and a driver integrated circuit electrically connected to the miniature light-emitting diodes and the sensor.

Other objectives, advantages and features of the present invention will be apparent from the following description referring to the attached drawings.

### BRIEF DESCRIPTION OF DRAWINGS

The present invention will be described via detailed illustration of three embodiments referring to the drawings wherein:

FIG. 1 is a top view of a touchscreen device according to the first embodiment of the present invention;

FIG. 2 is an enlarged partial side view of a LED module of the touchscreen device shown in FIG. 1;

FIG. 3 is an enlarged top view of a pixel unit of the touchscreen device shown in FIG. 1;

FIG. 4 is an enlarged side view of a pixel unit of a touchscreen device according to the second embodiment of the present invention; and

FIG. 5 is an enlarged side view of a pixel unit of a touchscreen device according to the third embodiment of the present invention.

### DETAILED DESCRIPTION OF EMBODIMENTS

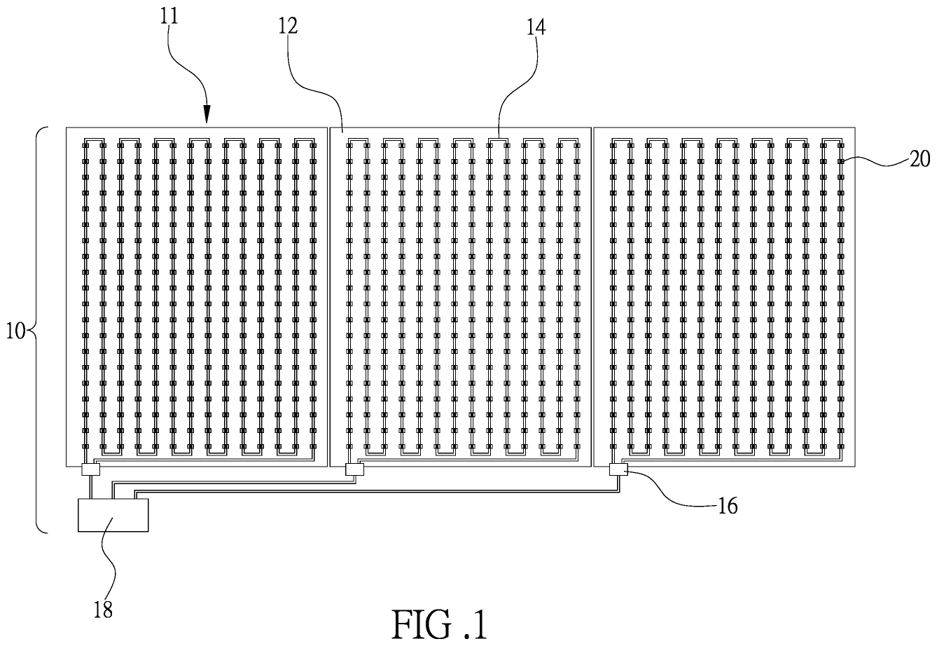

Referring to FIG. 1, a touch panel 10 includes a LED module 11, module connectors 16 and a controller 18 according to a first embodiment of the present invention. The LED module 11 includes multiple display substrates 12. Each of the display substrates 12 includes an array of pixel units 20 electrically connected to one another by an electronic circuit 14 laid out on the display substrate 12. The module connectors 16 electrically connect the electronic circuits 14 to one another to provide a collective loop. The controller 18 is electrically connected to all of the module connectors 16. The controller 18 is operable to determine brightness of each of the pixel units 20 and the location of a point of contact with a tip of a finger of a user.

The array of pixel units 20 refers to multiple rows of pixel units 20 and each row includes multiple pixel units 20. The distance between two adjacent ones of the pixel units 20 is large if the total amount of the pixel units 20 on each of the display substrates 12 is small. The distance between two adjacent ones of the pixel units 20 is small if the total amount of the pixel units 20 on each of the display substrates 12 is large. Thus, the amount of the pixel units 20 on each of the display substrates 12 is adjustable.

The display substrate 12 is an LED display substrate. The display substrate 12 is a flexible transparent substrate, an opaque substrate, a glass substrate or a printed circuit board (“PCB”) for example, not for a limiting purpose.

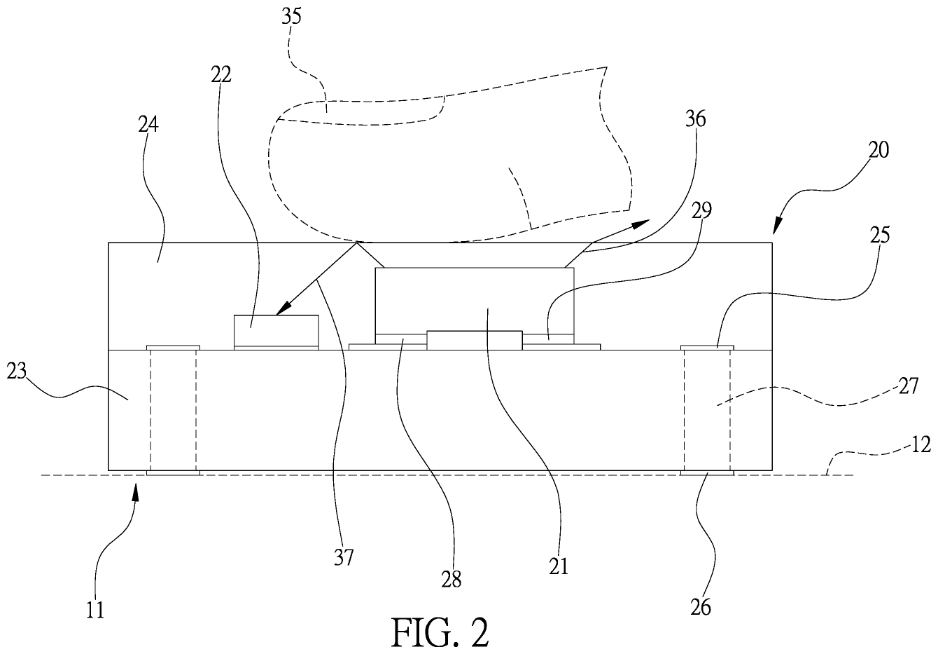

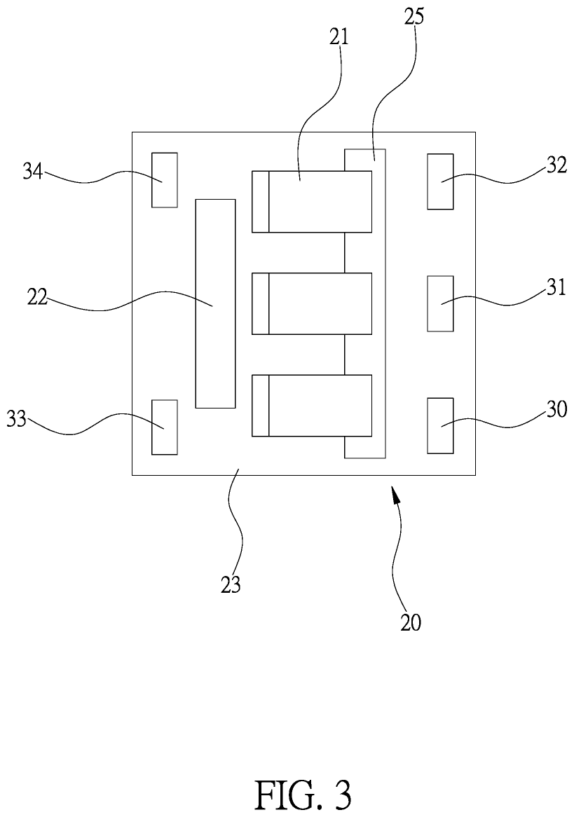

Referring to FIGS. 2 and 3, one of the pixel units 20 is shown and the following description will be given to this pixel unit 20 only. The pixel unit 20 includes three miniature light emitting diodes (“LED”s) 21, at least one sensor 22 and a driver IC 23. The LEDs 21 emit red light, green light and blue light, respectively. A through-silicon via (“TSV”) process is executed to make through-silicon vias 27 in the driver IC 23. The through-silicon vias 27 are filled with a conductive material such as copper, polysilicon and tungsten to electrically connect upper bond pads 25 to lower bond pads 26. The lower bond pads 26 are electrically connected to an electronic circuit of the display substrate 12 by soldering. The upper bond pads 25 are electrically connected to an N-electrode 28 and a P-electrode 29 of each of the miniature LEDs 21 and the sensor 22.

All of the pixel units 20 on each of the display substrates 12 are packed by a molded resin portion 24. The molded resin portion 24 is transparent. The molded resin portion 24 is a medium of light and provides a refractive interface and a reflecting face.

Under control of controller 18, the driver IC 23 actuates the miniature LEDs 21 to emit light. At an interface between the molded resin portion 24 and ambient air, some of the light is refracted and becomes refracted light 36 that goes to the exterior of the pixel unit 20. Hence, the touch panel 10 provides images like a display panel as of the conventional touchscreen device discussed in RELATED PRIOR ART.

When a tip of a finger 35 touches the molded resin portion 24, another portion of the light emitted from the miniature LEDs 21 is reflected and becomes reflected light 37. The reflected light 37 advances in the molded resin portion 24. The sensor 22 detects the reflected light 37. The sensor 22 changes at least one electric property according to the brightness of the reflected light 37. For example, the sensor 22 is a photo-resistor that causes a higher resistance as the reflected light 37 is brighter. The sensor 22 can be a photodiode or a photo-sensor in another embodiment.

The miniature LEDs 21 is smaller than 100 μm in diameter and smaller than 50 μm in thickness. Therefore, the volume of the miniature LEDs 21 is smaller than a typical LED that is 100 μm to 1000 μm in diameter and 100 μm to 500 μm in thickness. Thus, the tip of the finger 35 might touch multiple pixel units 20, blocks the light emitted from multiple groups of miniature LEDs 21, and actuate multiple sensors 22. However, based on a ratio of the resistances, the controller 18 can precisely determine the location of the point of contact of the tip of the finger 35 with the touch panel 10. Hence, there is no need to execute a process for making glass for a touch panel in addition to a display panel as of the conventional touchscreen device discussed in RELATED PRIOR ART. Thus, the touch panel 10 can be produced at a much lower cost.

Referring to FIG. 3, the driver IC 23 includes bond pads 30, 31, 32, 33 and 34. The bond pad 30 is a grounding portion. The bond pad 32 provides electricity for the driver IC 23. The bond pad 31 is an input port. The bond pad 34 is an output port. Thus, a clock data recovery is provided to allow the driver ICs 23 of the pixel units 20 are electrically connected to one another for display and communication of data. The bond pad 33 detects any damage of the driver IC 23. Once the driver IC 23 of one of the pixel units 20 fails to work, it will be separated from the driver ICs 23 of the other pixel units 20 electrically. Thus, a current that travels in the collective loop passes by the broken driver IC 23 and advances to the next normal driver IC 23. Hence, the broken driver IC 23 does not interfere with the normal operation of the other driver ICs 23.

If necessary, there can be provided an additional pulse width modulator (“PWM”) to avoid change in the wavelength or uneven brightness of analog dimming Alternatively, there can be a constant current driver to provide the miniature LEDs 21 with a constant current.

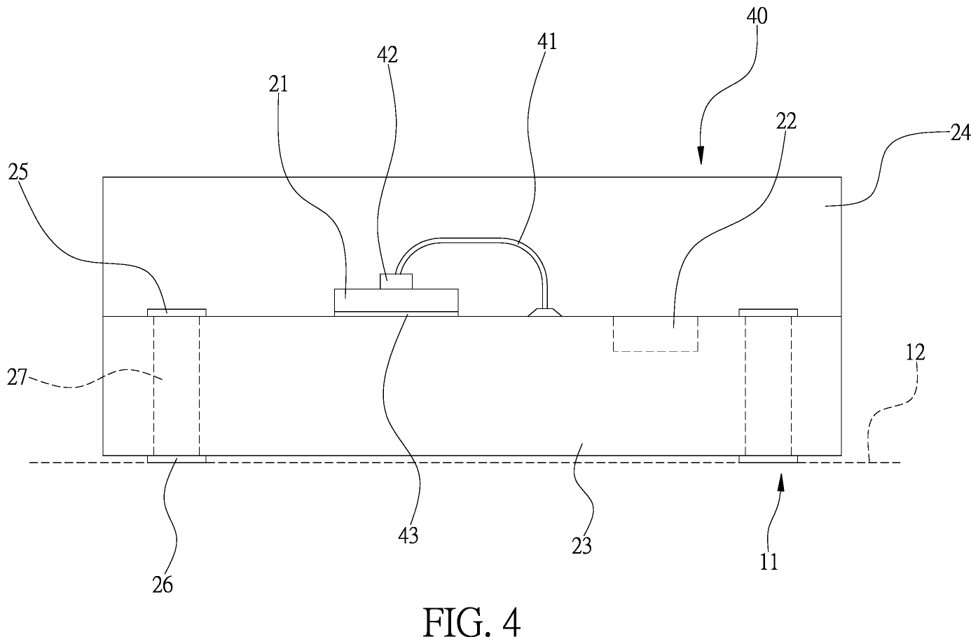

Referring to FIG. 4, there is shown a pixel unit 40 according to a second embodiment of the present invention. The second embodiment is identical to the first embodiment except for several things. Firstly, the sensor 22 is merged with the driver IC 23 to provide a single wafer.

Secondly, there is an additional metal wire 41 enclosed by the molded resin portion 24.

Thirdly, each of the miniature LEDs 21 includes an N-electrode 42 attached to an upper face and a P-electrode 43 attached to a lower face by soldering. The N-electrode 42 is electrically connected to the driver IC 23 via the metal wire 41.

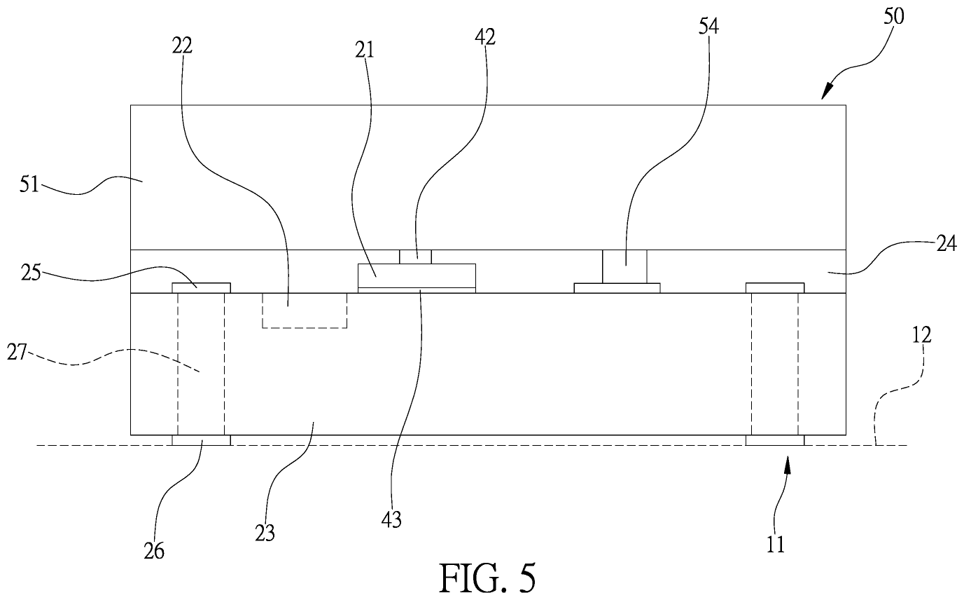

Referring to FIG. 5, there is a pixel unit 50 according to a third embodiment of the present invention. The third embodiment is identical to the second embodiment except for several things. Firstly, the pixel unit 50 does not include any metal wire.

Secondly, the pixel unit 50 includes an ITO transparent conductive film 51 and a miniature metal rod 54. The sensor 22 and the miniature metal rod 54 are located on two sides of the miniature LED 21.

The N-electrode 42 is electrically connected to the miniature metal rod 54 via the ITO transparent conductive film 51. The miniature metal rod 54 is electrically connected to another upper bond pad 25 of the driver IC 23.

The molded resin portion 24 encloses the miniature LEDs 21, the driver ICs 23, the upper bond pads 25, the ITO transparent conductive film 51 and the miniature metal rod 54. The molded resin portion 24 and the ITO transparent conductive film 51 do not block the light emitted from the miniature LEDs 21.

The present invention has been described via the illustration of the embodiments. Those skilled in the art can derive variations from the embodiments without departing from the scope of the present invention. Therefore, the embodiments shall not limit the scope of the present invention defined in the claims.

1. A touch panel comprising a display substrate, pixel units supported on the display substrate, an electronic circuit for electrically connecting the pixel units to one another, and a molded resin portion for enclosing the pixel units, wherein each of the pixel units comprises three miniature light-emitting diodes for emitting red light, green light and blue light respectively, a sensor, and a driver integrated circuit electrically connected to the miniature light-emitting diodes and the sensor.

2. The touch panel according to claim 1, wherein the display substrate is a light-emitting diode display panel.

3. The touch panel according to claim 1, wherein the display substrate is selected from the group consisting of a flexible transparent substrate, an opaque substrate, a glass substrate and a printed circuit board.

4. The touch panel according to claim 1, wherein the sensor is selected from the group consisting of a photo-resistor, a photo-diode and a photo-sensor.

5. The touch panel according to claim 1, wherein the molded resin portion covers a visible face of each of the miniature light-emitting diodes, a visible face of the sensor and a visible face of the driver integrated circuit.

6. The touch panel according to claim 1, wherein the molded resin portion provides an interface with ambient air to refract and reflect light emitted from the miniature light-emitting diodes.

7. The touch panel according to claim 1, wherein the sensor and the driver integrated circuit are made in a single wafer.

8. The touch panel according to claim 7, wherein the display substrate is a light-emitting diode display panel.

9. The touch panel according to claim 7, wherein the display substrate is selected from the group consisting of a flexible transparent substrate, an opaque substrate, a glass substrate and a printed circuit board.

10. The touch panel according to claim 7, wherein the sensor is selected from the group consisting of a photo-resistor, a photo-diode and a photo-sensor.

11. The touch panel according to claim 7, wherein the molded resin portion covers a visible face of each of the miniature light-emitting diodes, a visible face of the sensor and a visible face of the driver integrated circuit.

12. The touch panel according to claim 1, wherein the molded resin portion provides an interface with ambient air to refract and reflect light emitted from the miniature light-emitting diodes.
